(19) United States
(12) Patent Application Publication
(10) Pub. No.: US 2026/0328881 A1
(43) Pub. Date: Oct. 22, 2026

(54) SYSTEMS AND METHODS FOR INCREASED TEMPORAL RESOLUTION IN CHEMICAL EXCHANGE SATURATION TRANSFER

(71) Applicant: St. Jude Children’s Research Hospital Inc., Memphis, TN (US)

(72) Inventors: Puneet BAGGA, Memphis, TN (US); Ritambhar BURMAN, Memphis, TN (US)

(21) Appl. No.: 19/186,086

(22) Filed: Apr. 22, 2025

(51) Int. Cl. G01R 33/565; G01R 33/483

(52) U.S. Cl. CPC G01R 33/565; G01R 33/483

(57) ABSTRACT

A method includes applying a saturation pulse to the ROI for a positive frequency offset and a negative frequency offset based on the target molecule at a first time. The method includes determining initial MTR_{asym} data based on a first main magnetic field for the first time. The method includes identifying a correction function based on the initial MTR_{asym} data at the first time. The method includes applying the saturation pulse for the positive and negative frequency offsets to the ROI at a second time after the first time. The method includes determining subsequent MTR_{asym} data based on a second main magnetic field inhomogeneity for the second time. The method includes applying the correction function to the second magnetic field inhomogeneity. The method includes calculating a change in concentration of the target molecule between the first and second time based on the subsequent MTR_{asym} data.

### BACKGROUND

Conventional magnetic resonance imaging (MRI) techniques rely on magnetic resonance (MR) contrast agents to distinguish anatomical features. The MR contrast agents have to strike a balance between using enough MR contrast agents to achieve the desired contrast while avoiding perturbing the physiological environment and minimizing toxicity. Rather than using potentially toxic MR contrast agents, chemical exchange saturation transfer (CEST) techniques use exchangeable protons for MR contrast, which extends the range of possible MR contrast agents to include molecules with exchangeable protons. However, CEST techniques have low temporal resolution resulting in discrepancies in recovery time measurements.

### SUMMARY

In one example, a method for determining the concentration of a target molecule in a region of interest (ROI) in a subject is provided. The method includes applying a saturation pulse to the ROI for a positive frequency offset and a negative frequency offset corresponding to the positive frequency offset based on the target molecule at a first time. The method also includes determining initial magnetic transfer ratio asymmetry (MTR_{asym}) data based on a first main magnetic field for the first time. The method further includes identifying a correction function based on the initial MTR_{asym} data at the first time. The method yet further includes applying the saturation pulse for the positive frequency offset and the negative frequency offset to the ROI at a second time after the first time. The method includes determining subsequent MTR_{asym} data based on a second main magnetic field for the second time. The method also includes applying the correction function to the second main magnetic field. The method further includes calculating a change in concentration of the target molecule between the first time and the second time based on the subsequent MTR_{asym} data.

In another example, an MR system that includes a memory for storing machine-readable instructions and a processor core is provided. The processor core accesses the machine-readable instructions and executes the machine-readable instructions as operations. The operations include applying a saturation pulse for a frequency offset pair based on a target molecule to an ROI at a first time. The operations also include determining initial magnetic transfer ratio asymmetry (MTR_{asym}) data based on a first main magnetic field for the first time. The operations further include identifying a correction function based on the initial MTR_{asym} data at the first time. The operations yet further include applying the saturation pulse for the frequency offset pair to the ROI at a second time after the first time. The operations include determining subsequent MTR_{asym} data based on a second main magnetic field for the second time. The operations also include applying the correction function to the second main magnetic field. The operations further include calculating a change in concentration of the target molecule between the first time and the second time based on the subsequent MTR_{asym} data.

In yet another example, a non-transitory machine-readable medium having machine-readable instructions for an MR system causing a processor to execute operations. The operations include applying a saturation pulse for a positive frequency offset and a negative frequency offset corresponding to the positive frequency offset based on the target molecule to the ROI at a first time. The operations also include determining initial magnetic transfer ratio asymmetry (MTR_{asym}) data based on a first main magnetic field for the first time. The operations further include identifying a correction function based on the initial MTR_{asym} data at the first time. The operations yet further include applying the saturation pulse for the positive frequency offset and the negative frequency offset to the ROI at a second time after the first time. The operations include determining subsequent MTR_{asym} data based on a second main magnetic field for the second time. The operations also include applying the correction function to the subsequent MTR_{asym} data. The operations further include calculating a change in concentration of the target molecule between the first time and the second time based on the subsequent MTR_{asym} data.

### BRIEF DESCRIPTION OF THE DRAWINGS

FIG. 1 illustrates an example component diagram of a system for chemical exchange saturation transfer (CEST).

FIG. 2 illustrates an example of a magnetic resonance (MR) device having an examination volume.

FIG. 3 illustrates a cross-sectional view of an example region of interest (ROI) of a subject.

FIG. 4 illustrates an example saturation offset graph for a magnetization signal at a positive frequency offset and a negative frequency offset.

FIG. 5 illustrates an example of a timing diagram for magnetic transfer ratio asymmetry data.

FIGS. 6A-C illustrate examples of the initial MTR_{asym} data as a function of magnetic field strength with regard to a lateral gastrocnemius (LG), a medial gastrocnemius (MG), and a soleus, respectively.

FIGS. 7A-C illustrate examples of the subsequent MTR_{asym} data as a function of magnetic field strength with regard to the LG, the MG, and the soleus, respectively.

FIGS. 8A-C illustrate examples of the CEST data as a function of corrected magnetic field strength with regard to the LG, the MG, and the soleus, respectively.

FIG. 9 illustrates an example timing diagram for a CEST session.

FIG. 10 illustrates an example recovery rate graph of the CEST data as a function of time with regard to the LG, the MG, and the soleus.

FIG. 11 is flow chart of an example method of quantifying CEST with respect to a target molecule.

FIG. 12 is an illustration of an example computer-readable medium or computer-readable device including processor-executable instructions configured to embody one or more of the provisions set forth herein.

### DETAILED DESCRIPTION

Chemical exchange saturation transfer (CEST) detects the presence of molecules in a subject non-invasively. For example, creatine-weighted chemical exchange saturation transfer (CrCEST) MRI can non-invasively map creatine (Cr) recovery in skeletal muscle. Mapping Cr provides insight into the health of a subject at the cellular level. Mitochondrial oxidative phosphorylation (OXPHOS) is the primary cellular process that generates adenosine triphosphate (ATP), the primary energy currency of cells. The creatine kinase (CK) reaction is a metabolic chemical reaction that replenishes adenosine triphosphate (ATP). Derived from the conversion of phosphocreatine (PCr) to Cr by the CK reaction, ATP provides a chemical energy source that governs muscle contraction. While ATP represents the fundamental energy currency, PCr serves as the reservoir of cellular energy. During exercise, PCr is depleted to maintain the ATP supply, leading to an increase in Cr concentration and then decaying to a baseline post-exercise. The Cr concentration may be used to detect impaired OXPHOS. For example, the Cr concentration not recovering as expected may be indicative of neuromuscular disorders, aging, cancer, and cancer treatments.

Each molecule of creatine includes exchangeable protons and thus be used as a target molecule for CEST. The exchangeable protons resonate at different frequencies than bulk water protons when selectively saturated using radio frequency (RF), resulting in the water signal becoming attenuated. In particular, prolonged irradiation leads to substantial enhancement of this saturation effect, which eventually becomes visible on the water signal, allowing the presence of Cr to be imaged indirectly. By analyzing the differences in signal attenuation at different frequency offsets around the water resonance peak, the concentration of Cr in an anatomical feature can be determined. Thus, the target molecule is isolated to quantify specific molecular interactions within the tissue of the subject.

In traditional CEST, frequency offsets are measured at multiple frequency offsets about a frequency offset based on the target molecule. For example, for a frequency offset pair of ±1.8 parts per million (ppm), the adjacent frequency offset pairs of ±1.5 ppm and ±2.1 ppm are measured. Each frequency offset pair has an acquisition time, such as a ten second acquisition for a total thirty second temporal resolution for the three frequency offset pairs. The adjacent frequency offsets are used to correct the inhomogeneity effects of the main magnetic field (B₀). However, for target molecules that change concentration quickly, such as metabolites, the temporal resolution is too long to model the change in concentration and is prone to noise.

The systems and methods herein increase the temporal resolution by reducing the measured frequency offset pairs. As one example, the target molecule is Cr and is associated with a frequency offset pair of ±1.8 ppm, and initial magnetic transfer ratio asymmetry (MTR_{asym}) data are determined at a first time. For example, the signal acquisition for the single frequency offset pair may be ten seconds. Without the adjacent frequency offset pairs to correct the effects of the B₀ inhomogeneity, correction analysis is performed to identify a correction function for the initial MTR_{asym} data. The correction function is then applied to the second B₀ inhomogeneity for the subsequent MTR_{asym} data at a second time after the first time. The CEST values are determined by subtracting the correction function as applied to the second B₀ inhomogeneity from the subsequent MTR_{asym} data. Therefore, the systems and methods herein account for inhomogeneity effects and reduce the signal acquisition time, for example, from thirty seconds to ten seconds, increasing the temporal resolution. Accordingly, target molecules with shorter recovery times can be isolated and quantified in the tissue.

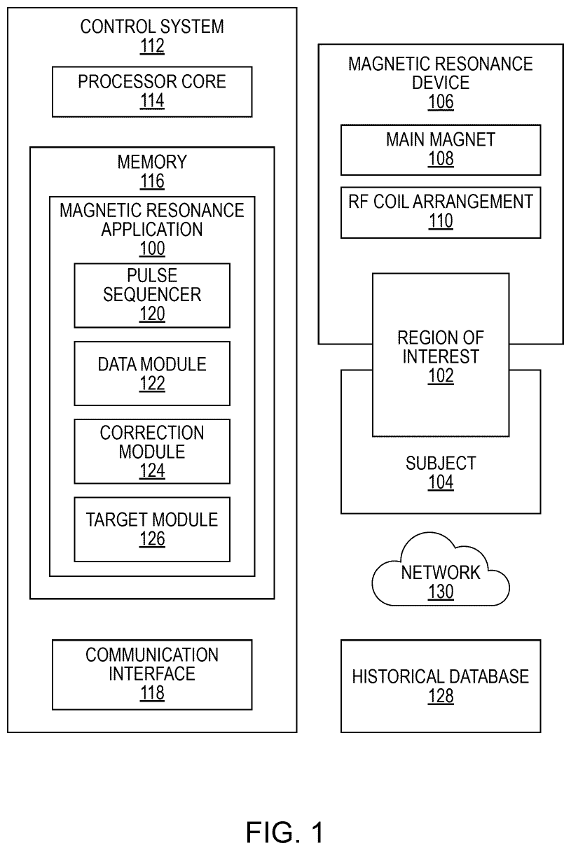

FIG. 1 illustrates an example component diagram of a system for CEST. The magnetic resonance application 100 is employed to determine a concentration in a target molecule in a region of interest (ROI) 102 of a subject 104. The ROI 102 is examined with an MR device 106. The MR device 106 includes a main magnet 108 for generating a stationary homogeneous main magnetic field in the examination volume. The MR device 106 also includes at least one RF coil arrangement 110 for generating RF fields in the examination volume and/or for receiving MR signals from the subject 104. The RF coil arrangement 110 comprises a plurality of independent resonator elements. The RF coils can act like a transmitter, a receiver, or both. The resonator elements are alternately tuned to one of at least two different MR resonance frequencies, and each resonator element is associated with a separate signal transmission and/or signal reception channel of the MR device 106.

A control system 112 controls the main magnet 108 and the RF coil arrangement 110. The control system 112 includes a processor core 114, a memory 116, and a communication interface 118, which are operably connected for computer communication. The processor core 114 processes signals and performs general computing to execute instructions stored in the memory 116. The instructions cause the processor core 114 to execute operations. The processor core 114 can be a variety of various processors including multiple single and multicore processors, co-processors, processor cores, and other multiple single and multicore processor and co-processor architectures.

The memory 116 may store an operating system that controls or allocates resources of the MR application 100. The memory 116 represents a non-transitory machine-readable medium (or other medium), such as RAM, a solid-state drive, a hard disk drive or a combination thereof. The MR application 100 includes modules including a pulse sequencer 120, a data module 122, a correction module 124, and a target module 126 and stores machine-readable instructions associated with the modules. The MR application 100 could be representative of a single instance of hardware or multiple instances of hardware with applications executing across the multiple instances (i.e., distributed) of hardware (e.g., computers, routers, memory, processors, or a combination thereof). Alternatively, the MR application 100 could be implemented on a single dedicated server. In various examples, the MR application 100 can include more or fewer of the modules.

The communication interface 118 provides software and hardware to facilitate data input and output between the MR application 100 and data sources, such as a historical database 128 via a network 130. The network 130 is, for example, a data network, the Internet, a wide area network (WAN) or a local area (LAN) network. The network 130 serves as a communication medium to various remote devices (e.g., databases, web servers, remote servers, application servers, intermediary servers, client machines, other portable devices).

The pulse sequencer 120 causes the MR device 106 to apply a saturation pulse to the ROI 102 of the subject 104 at a first time. The saturation pulse includes RF pulse(s) to saturate protons in a target molecule to exchange with unsaturated water protons. For example, the saturation pulse is a 90° RF pulse at a frequency offset corresponding to the target molecule. While examples are described with respect to creatine as the target molecule, other target molecules may include gamma-aminobutyric acid, glutamate, glucose, myo-inositol, ATP, phospho-creatine, glycine, proline, albumin, alanine, or aspartate. The saturation pulse may be determined based on historical data. For example, the pulse sequencer 120 may identify a target molecule and request and receive a corresponding saturation pulse from the historical database 128. Alternatively, the pulse sequencer 120 may calculate the saturation pulse or receive the saturation pulse as input.

The saturation pulse is centered at frequency offsets other than water resonance frequency, leading to a corresponding decrease in the water signal intensity within the ROI 102. As one example, the water signal intensity is influenced by a positive frequency offset of +1.8 ppm and a negative frequency offset of −1.8 ppm, direct water saturation (DS), nuclear Overhauser effect (NOE) at −3.5ppm, amide proton transfer (APT) at 3.5ppm. In response the application of the saturation pulse, phase encoded MR signals are generated, which are scanned by means of the RF coil arrangement 110, for example including RF receiving antennas, in order to obtain information from the subject 104.

The data module 122 determines initial magnetic transfer ratio asymmetry (MTR_{asym}) data based on a first main magnetic field for the first time. The initial MTR_{asym} data is calculated by comparing the signal intensity difference between the positive frequency offset and the negative frequency offset on either side of the water resonance peak. In some examples, the initial MTR_{asym} data is plotted relative to the first main magnetic field.

The correction module 124 identifies a correction function based on the initial MTR_{asym} data at the first time. The correction module 124 performs a regression analysis including one or more of linear regression, quartic regression, logistic regression, polynomial regression, Poisson regression, lasso regression, ridge regression, and a partial least squares (PLS) regression, among others. For example, the correction module 124 performs quartic regression and identifies the correction function as a fourth order polynomial fit to the initial MTR_{asym} data. The correction function models the inhomogeneity of the main magnetic field at the first time.

The pulse sequencer 120 causes the MR device 106 to apply the saturation pulse for the positive frequency offset and the negative frequency offset to the ROI 102 at a second time after the first time. The data module 122 determines subsequent MTR_{asym} data based on a second main magnetic field for the second time. The first time and the second time may be separated by an event that physiologically affects the ROI 102. As one example, the event may be an exercise of the muscles in the ROI 102 of the subject 104 such that the first time occurs in a pre-event period before the exercise and the second time occurs in a post-event period after the exercise. The exercise may cause muscles in the ROI 102 to undergo a chemical reaction that effects the anatomy of the subject 104. For example, the metabolic chemical reaction may be a CK reaction leading to an increase in Cr concentration during the event which then falls to a baseline in the post-event period. Therefore, the event results in a change in the concentration of the target molecule.

The correction module 124 applies the correction function to the subsequent MTR_{asym} data to correct the inhomogeneity effects. In some examples, applying the correction function includes fitting the correction function to the subsequent MTR_{asym} data to model the second B₀ inhomogeneity for the subsequent MTR_{asym} data_{.} The target module 126 calculates a change in concentration of the target molecule between the first time and the second time based on the subsequent MTR_{asym} data. As one example, the target module 126 calculates the concentration of the target molecule as CEST values at different point in time, such as the first time before the event and the second time after the event. In another example, the CEST values are calculated to determine a recovery rate of the target molecule during the post-event period.

As used in this application, the terms “component”, “module,” “system”, “interface”, and the like are generally intended to refer to a computer-related entity, either hardware, a combination of hardware and software, software, or software in execution. For example, a module may be, but is not limited to being, a process running on a processor, a processor, an object, an executable, a thread of execution, a program, or a computer. By way of illustration, both an application running on a controller and the controller may be a component. One or more components residing within a process or thread of execution and a component may be localized on one computer or distributed between two or more computers.

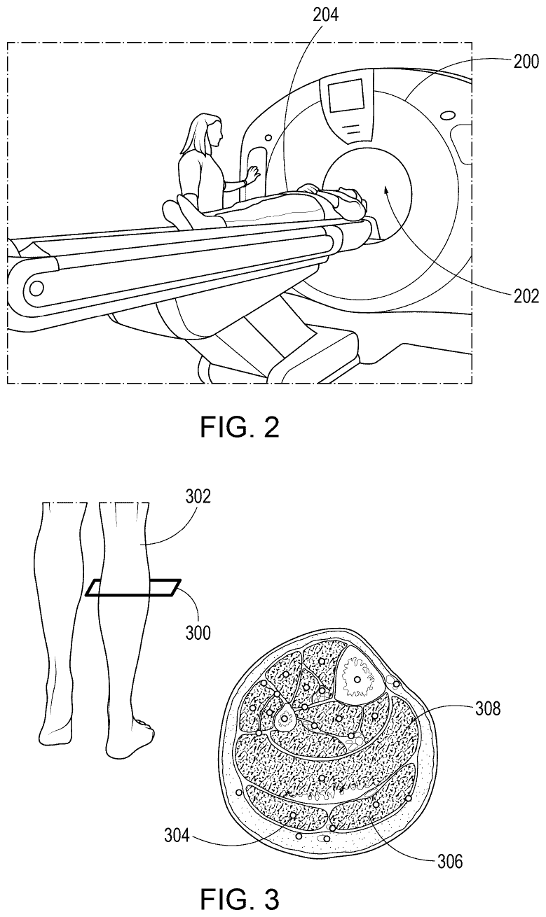

FIG. 2 illustrates an example of a MR device 200 (e.g., the MR device 106 of FIG. 1) having an examination volume 202 for a portion of a subject 204 (e.g., the subject 104 of FIG. 1) corresponding to an ROI (e.g., the ROI 102 of FIG. 1). The examination volume 202 may be defined as an interior of the MR device 200. For example, the examination volume 202 is a bore of the MR device 200. Alternatively, the examination volume 202 may be a volume of space external to the MR device 200. For example, suppose the MR device 200 is handheld, then the examination volume 202 may be a volume located between the MR device 200 and the subject 204.

The subject 204 is a biological entity and may be a human (e.g., an adult, a child, an infant) or an animal (e.g., a pet, a zoo animal, an animal from a preserve, etc.). The ROI includes one or more anatomical features, such as organs (e.g., the brain, the heart, etc.), skeletal system (e.g., spinal cord, limbs, etc.), skeletal muscles, ligaments, tendons, soft tissue, and vascular anatomy, among others of the subject 204. For example, the ROI may include a portion of a first muscle and a second muscle of the subject 204.

The ROI is targeted by the MR device 200 in the examination volume 202. The examination volume 202 provides area for the subject 204 to exercise. An exercise is a movement or isometric application of force of a portion of the subject 204. The movements may include inversion, eversion, adduction, abduction, flexion, rotation of muscles in the ROI. For example, the ROI is in the calf of the subject 204 and the exercise is a dorsiflexion and plantar flexion that can be performed within the examination volume 202. As another example, the exercise may include an inversion and eversion of the foot. The exercise may include a repetition of the movements of the subject 204.

FIG. 3 illustrates a cross-sectional view of an example ROI 300 (e.g., the ROI 102 of FIG. 1) of a subject 302 (e.g., the subject 104 of FIG. 1, the subject 204 of FIG. 2). For example, if the ROI 300 is the calf of a subject 302, the ROI 300 may be a slice of a transverse plane including one or more portions of skeletal muscles in the calf. A first muscle may be the lateral gastrocnemius (LG) 304, a second muscle may be the medial gastrocnemius (MG) 306, and the third muscle may be the soleus 308, which together form the triceps surae. Within the ROI 300, one or more of the muscles is the focus of the analysis. While the following examples are described with respect to the three muscles of the calf, more or fewer anatomical features or different anatomical features may be included in the ROI 300.

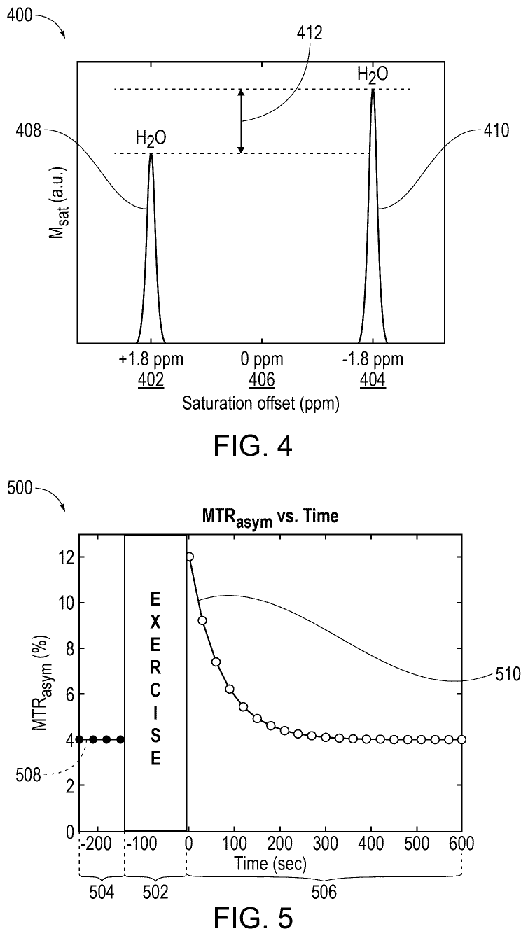

FIG. 4 illustrates an example saturation offset graph 400 for a magnetization signal at a positive frequency offset and a negative frequency offset. The magnetization signal is generated in response to applying a saturation pulse for a positive frequency offset 402 and a negative frequency offset 404 around the water reference peak 406 which is defined at 0 ppm. Because the saturation pulse does not include the conventional six frequency offsets, the temporal resolution is increased by a factor of three by eliminating the time incurred to measure the eliminated frequency offsets. Instead, the saturation pulse is for a single frequency offset pair. The magnetization signal includes a first peak 408 for the positive frequency offset 402 and a second peak 410 at the negative frequency offset 404.

The MTR_{asym} data is calculated as the difference 412 in amplitude between the first peak 408 and the second peak 410 to quantify specific molecular interactions for each pixel within the ROI (e.g., the ROI 102 of FIG. 1, the ROI 300 of FIG. 3) of the subject (e.g., the subject 104 of FIG. 1, the subject 204 of FIG. 2, the subject 302 of FIG. 3). Thus, the MTR_{asym} data is the difference in signal intensity between the positive frequency offset 402 and the negative frequency offset 404 on either side of the water reference peak 406.

FIG. 5 illustrates an example of a timing diagram 500 for the MTR_{asym} data. The timing diagram 500 illustrates the changes in MTR_{asym} data of the target molecule, such as Cr, in response to an event 502 in time, such as exercise, resulting in a pre-event period 504 and a post-event period 506. As one example, to measure the efficiency of OXPHOS, the concentration of Cr can be measured to determine the rate that ATP is being replenished in response to exercise. The MTR_{asym} data is measured in the pre-event period 504 and the post-event period 506. In the pre-event period 504, MTR_{asym} data defines a baseline 508. In the post-event period 506, the MTR_{asym} data defines a recovery rate 510 of the target molecule.

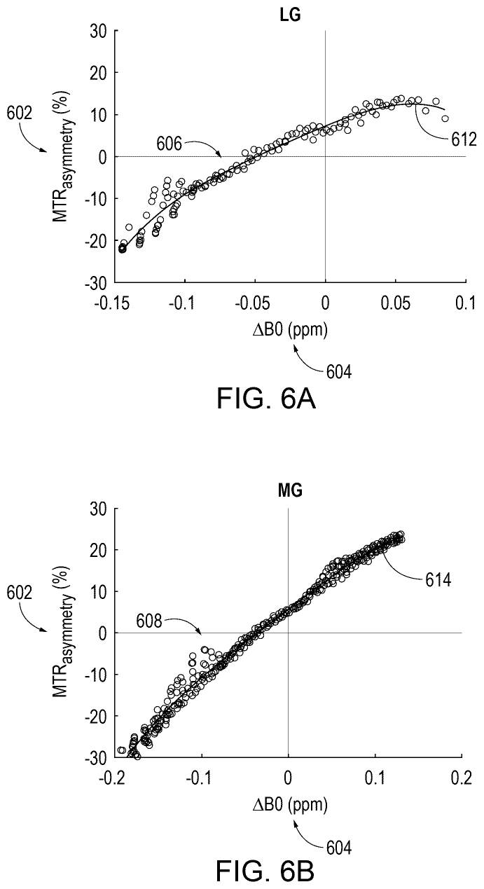

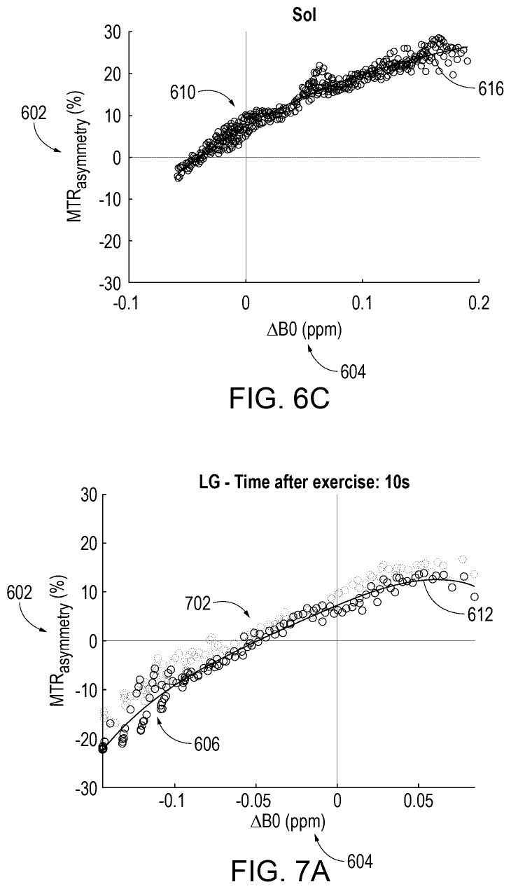

FIGS. 6A-C illustrates an example of the initial MTR_{asym} data mapped as a function of MTR_{asym} 602 versus magnetic field inhomogeneity 604 with regard to the ROI (e.g., the ROI 102 of FIG. 1, the ROI 300 of FIG. 3) at a first time. For example, the ROI may include a portion of one or more of the LG (e.g., the LG 304 of FIG. 3), the MG (e.g., the MG 306 of FIG. 3), and the soleus (e.g., the soleus 308 of FIG. 3). The initial MTR_{asym} data is mapped with respect to the individual anatomical features within the ROI, here the different muscles. For example, in FIG. 6A, the initial LG MTR_{asym} data 606, representing pixels or voxels of the LG from the pre-event period (e.g. the pre-event period 504), is plotted as a function of the main magnetic field inhomogeneity. The initial LG MTR_{asym} data 606 is mapped versus main magnetic field inhomogeneity, at each pixel within the LG prior to the event (e.g., the event 502 of FIG. 5), for example, at rest, prior to exercise.

Different muscles experience the magnetic field inhomogeneity 604, including strength and inhomogeneity, differently based on their different positions in a MR device (e.g., the MR device 106 of FIG. 1, the MR device 200 of FIG. 2). For example, in FIG. 6B, the initial MG MTR_{asym} data 608 representing pixels or voxels of the MG from the pre-event period is plotted as a function of the MTR_{asym} 602 versus the magnetic field inhomogeneity 604 at the first time. In FIG. 6C, the initial soleus MTR_{asym} data 610 representing pixels or voxels of the soleus from the pre-event period is plotted as a function of the MTR_{asym} 602 versus the magnetic field inhomogeneity 604 at the first time. Magnetic field inhomogeneity, based on the MR device, distorts CEST imaging results by causing variations in the signal intensity across different tissue regions, leading to inaccurate quantification of the CEST effect if not corrected.

A correction function is identified based on the initial MTR_{asym} data at the first time. The correction function is determined for the individual anatomical features because the anatomical features experience the main magnetic field, B₀, differently. For example, with respect to FIG. 6A, a first correction function 612 is calculated based on a regression analysis of the initial LG MTR_{asym} data 606. For example, quartic regression may be used to identify the first correction function 612 as a fourth order polynomial. A second correction function 614 based on the initial MG MTR_{asym} data 608 for the MG and a third correction function 616 based on the initial soleus MTR_{asym} data 610 for the soleus.

The correction functions 612-616 are represented as f (ΔB₀_{ₚᵣₑ}(i)) such that the initial MTR_{asym} data, MTR_{asym}_{ₚᵣₑ}, of the first time at the positive frequency offset (e.g., the positive frequency offset 402 of FIG. 4) and the negative frequency offset (e.g., the negative frequency offset 404 of FIG. 4) is given by:

MTR_{asym}_{ₚᵣₑ}(i)=f(ΔB₀_{ₚᵣₑ}(i)),

where i corresponds to a pixel and ΔB₀_{ₚᵣₑ} is the first main magnetic field inhomogeneity.

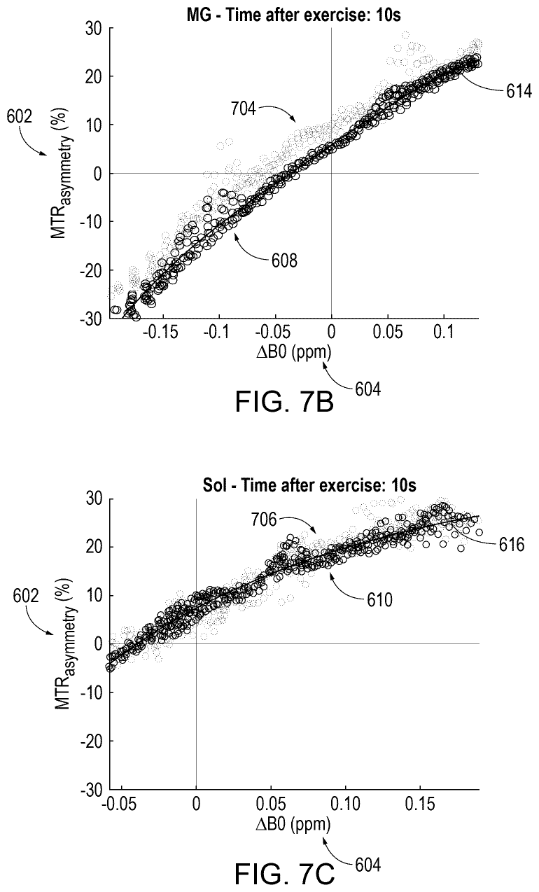

FIGS. 7A-C illustrates an example of the subsequent MTR_{asym} data MTR_{asym} data over the initial MTR_{asym} data as shown with respect to FIG. 6A-C. Like FIG. 6A-C, FIGS. 7A-C are mapped as a function of MTR_{asym} 602 versus magnetic field inhomogeneity 604 with regard to the LG (e.g., the LG 304 of FIG. 3), the MG (e.g., the MG 306 of FIG. 3), and the soleus (e.g., the soleus 308 of FIG. 3), respectively. For purposes of simplification, FIGS. 6A-7C employ the same reference numbers to denote the same features.

In FIG. 7A, subsequent LG MTR_{asym} data 702, representing pixels or voxels of the LG in the ROI from the post-event period (e.g. the post-event period 506 of FIG. 5), is plotted as a function of the main magnetic field inhomogeneity. The subsequent LG MTR_{asym} data 702 is mapped against the main magnetic field inhomogeneity, at each pixel or voxel within the LG after the event (e.g., the event 502 of FIG. 5), for example, at rest, prior to exercise. In FIG. 7B, the subsequent MG MTR_{asym} data 704 representing pixels or voxels of the MG from the post-event period is also plotted as a function of MTR_{asym} 602 versus magnetic field inhomogeneity 604 at the second time. In FIG. 6C, the subsequent soleus MTR_{asym} data 706 representing pixels or voxels of the soleus from the pre-event period is plotted as a function of the MTR_{asym} 602 versus magnetic field inhomogeneity 604 at the second time.

The correction functions 612-616 map the B₀ inhomogeneity at each pixel or voxel within the ROI (e.g., the ROI 102 of FIG. 1, the ROI 300 of FIG. 3), here the muscle groups, at rest prior to exercise to the MTR_{asym} 602 at the same location. For example, the correction function 612 of the initial LG MTR_{asym} data 606 predicts the inhomogeneity of the subsequent LG MTR_{asym} data 702. The correction function 612 may model the subsequent LG MTR_{asym} data 702 with a vertical shift in the MTR_{asym} 602. The concentrations of the target molecule are calculated based on the subsequent MTR_{asym} data excluding the post-event inhomogeneity as a function of the corresponding correction function.

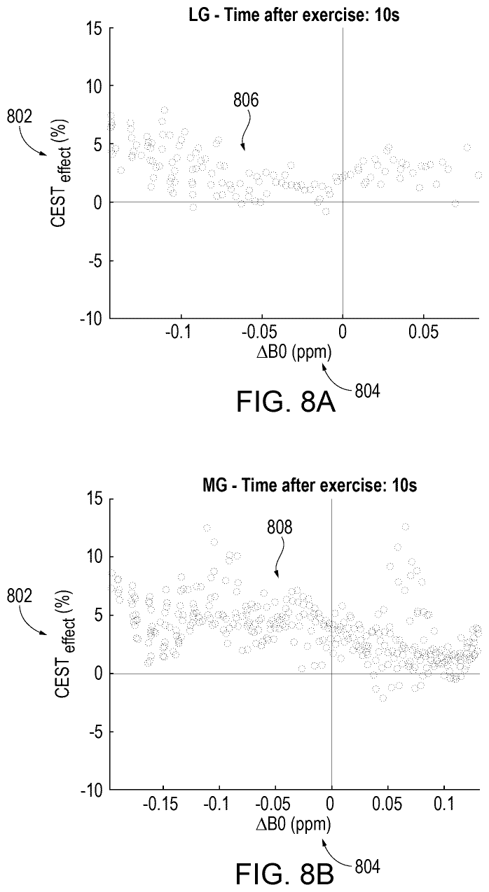

FIGS. 8A-C illustrates an example of the CEST effect 802 as a function of the magnetic field strength 804 with regard to the LG (e.g., the LG 304 of FIG. 3), the MG (e.g., the MG 306 of FIG. 3), and the soleus (e.g., the soleus 308 of FIG. 3), respectively. The CEST effect 802 is based on a correction function (e.g., the correction function 612-616 of FIG. 6A-7C). The correction function maps the inhomogeneity of the B₀ at each pixel within a ROI (e.g., the ROI 102 of FIG. 1, the ROI 300 of FIG. 3) at a first time. The correction function is used to model the inhomogeneity of the B₀ at the second time. For example, by measuring the B₀ inhomogeneity map after exercise, the corrected function is applied to predict the MTR_{asym} for the new B₀ induced by the movement of the exercise and is given by:

MTR_{asym}_{ₚₒₛₜ}(i)=ΔCEST(i)+f(ΔB₀_{ₚₒₛₜ}(i)).

Thus, the change in the concentration, ΔCEST, of the target molecule from the first time to the second time is given by:

ΔCEST(i)=MTR_{asym}_{ₚₒₛₜ}(i)−f(ΔB₀_{ₚₒₛₜ}(i))

Accordingly, the ΔCEST is calculated by subtracting the corrected B₀ inhomogeneity from the subsequent MTR_{asym} data acquired after the event. The change in the concentration of the target molecule is calculated as highly temporally resolved CEST values at every pixel or voxel in the ROI. For example, the ΔCEST is calculated to determine the change from the first time to a second time after the event. In FIG. 8A, the LG ΔCEST 806 is mapped relative to main magnetic field includes inhomogeneity, at each pixel within the LG after the event. In FIG. 8B, the MG ΔCEST 808 is mapped relative to main magnetic field includes inhomogeneity, at each pixel within the MG after the event. In FIG. 8C, the soleus ΔCEST 810 is mapped relative to main magnetic field includes inhomogeneity, at each pixel within the soleus after the event. Accordingly, the ΔCEST is calculated for the different anatomical features in the ROI based on the corresponding correction function being applied to the second main magnetic field for the second time and then subtracted from the corresponding subsequent MTR_{asym} data.

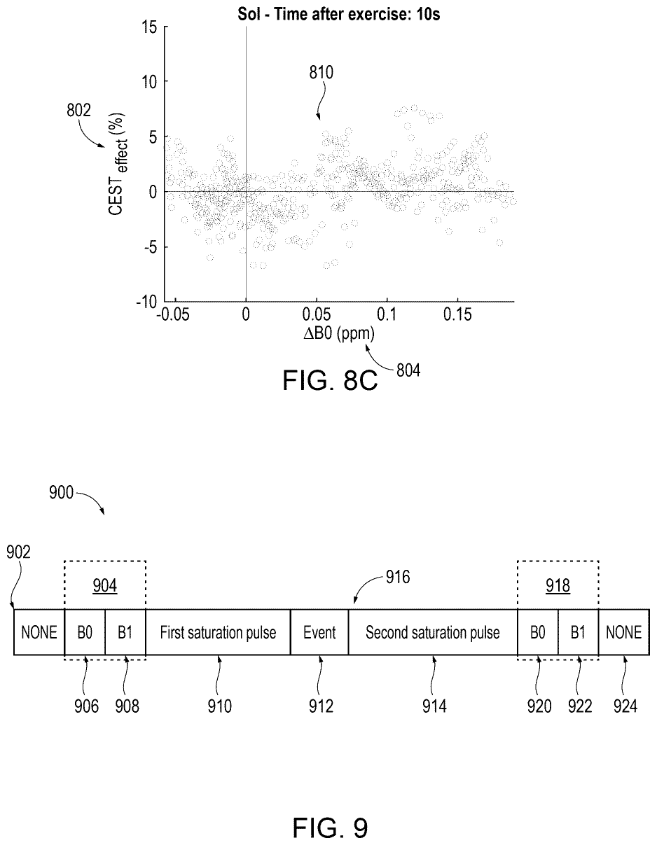

FIG. 9 illustrates an example timing diagram 900 for a CEST session. At a first time 902, “none” image captures the anatomy of the muscle without applying any saturation. The acquisition 904 may include mapping sequences for B₀ inhomogeneity 906 and B₁ inhomogeneity 908. A first saturation pulse 910, including a frequency or a range of frequencies, is applied. The first saturation pulse 910 is applied to substantially saturate magnetization corresponding to an exchangeable proton of a target molecule in the ROI (e.g., the ROI 102 of FIG. 1, the ROI 300 of FIG. 3), which generates the initial MTR_{asym} data (e.g., the initial MTR_{asym} data 606-610 of FIGS. 6A-6C). The initial MTR_{asym} data is measured in a pre-event period (e.g., the pre-event period 504 of FIG. 5) by sampling a frequency offset pair around the water resonance peak. The frequency offset pair includes a positive frequency offset (e.g., the positive frequency offset 402 of FIG. 4) and a negative frequency offset (e.g., the negative frequency offset 404 of FIG. 4) equidistant from the water reference frequency. The initial MTR_{asym} data defines a baseline (e.g., the baseline 508 of FIG. 5).

After an event 912, the subject (e.g., the subject 104 of FIG. 1, the subject 204 of FIG. 2, e.g., the subject 302 of FIG. 3) enters a post event period 916 (e.g., the post-event period 506 of FIG. 5). The event 912 may be an exercise of muscles in the ROI. In the post event period 916, the exercise is not performed. At a second time in the post event period 916, a second saturation pulse 914 is applied to the ROI to substantially saturate magnetization corresponding to the exchangeable protons of the target molecule in the ROI and measure the recovery rate of the target molecule in response to the event 912. Subsequent MTR_{asym} data (e.g., the subsequent MTR_{asym} data 702-706 of FIG. 7) is measured in or after the post event period 916 by sampling the positive frequency offset and the negative frequency offset around the water resonance peak. Rather than having to sample a plurality of offset pairs, a single offset pair is sampled thereby reducing acquisition time and increasing temporal resolution. Increased temporal resolution improves detection of rapid changes in concentrations of target molecules. The acquisition 918 may include a second B0 inhomogeneity 920 and B1 inhomogeneity mapping 922 sequence. It may be followed by another “none” image 924 acquired without saturation to acquire the anatomy.

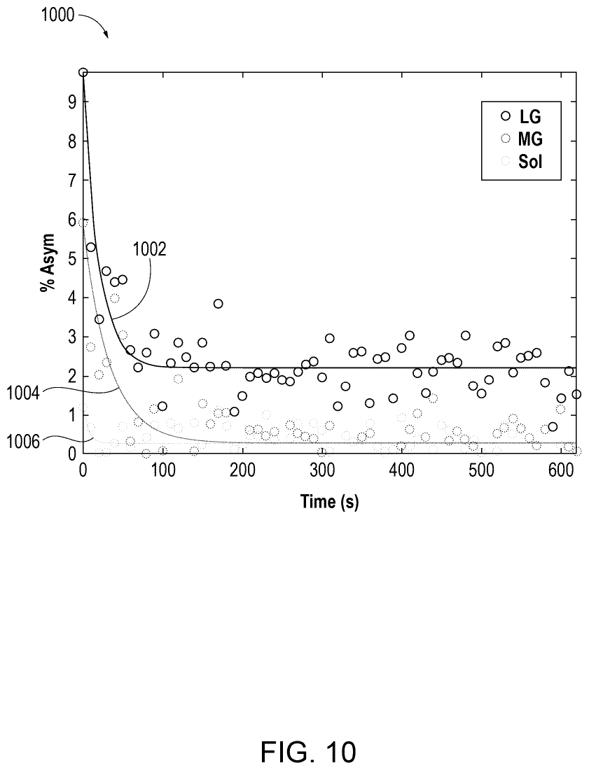

Continuing the example from above with respect to the cross-section of the calf of a subject (e.g., the subject 104 of FIG. 1, the subject 204 of FIG. 2, e.g., the subject 302 of FIG. 3) as the ROI (e.g., the ROI 102 of FIG. 1, the ROI 300 of FIG. 3), FIG. 10 illustrates an example recovery rate graph 1000 of the CEST data as a function time with regard to LG recovery curve 1002, MG recovery curve 1004, and soleus recovery curve 1006. The LG recovery curve 1002 illustrates the exponential decay of the concentration of the target molecule in the LG of the ROI. The MG recovery curve 1004 illustrates the exponential decay of the concentration of the target molecule in the MG of the ROI. The soleus recovery curve 1006 illustrates the exponential decay of the concentration of the target molecule in the soleus of the ROI.

In an example in which the target molecule is Cr, the concentration of Cr changes rapidly in response to metabolic events. During exercise, PCr is depleted to maintain the ATP supply leading to an increase Cr concentration which then rapidly decays to a baseline (e.g., the baseline 508 of FIG. 5). The increased temporal resolution improves sampling of the recovery curves 1002-1006 exponentially decay allowing for faster and more precise mapping of an ROI, such as skeletal muscle, recovery after an event such the exercise.

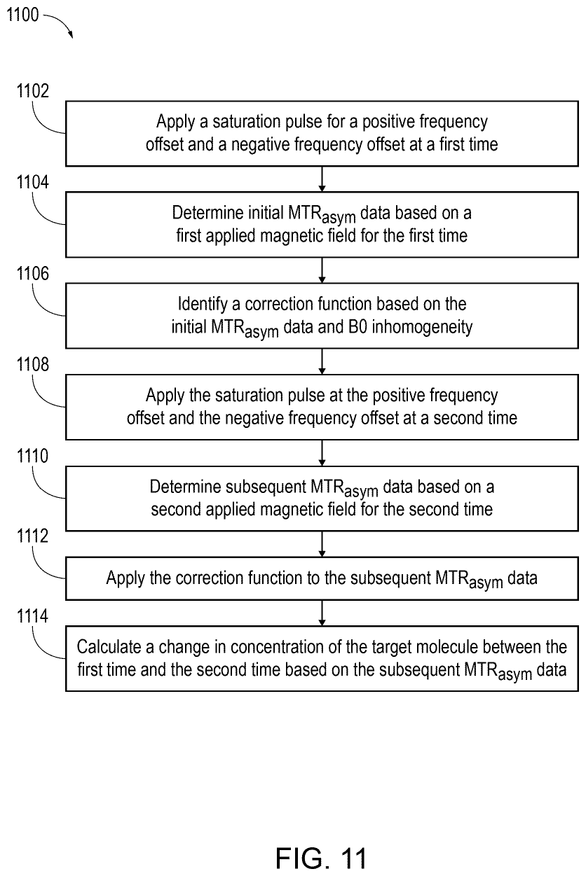

FIG. 11 is an illustration an example method of quantifying chemical exchange saturation transfer (CEST) with respect to a target molecule. FIG. 11 will also be described with reference to FIGS. 1-10. For simplicity, the method 1100 will be described as a sequence of blocks, but it is understood that the elements of the method 1100 can be organized into different architectures, elements, stages, and/or processes.

At block 1102, the method 1100 includes applying a saturation pulse for a positive frequency offset (e.g., the positive frequency offset 402 of FIG. 4) and a negative frequency offset (e.g., the negative frequency offset 404 of FIG. 4) corresponding to the positive frequency offset based on the target molecule to the ROI (e.g., the ROI 102 of FIG. 1, the ROI 300 of FIG. 3) at a first time (e.g., the first time 902 of FIG. 9). For example, if the target molecule is creatine, the frequency offset pair includes a single positive frequency offset of 1.8 ppm and a single negative frequency offset of −1.8ppm about a water reference peak. The ROI may include one or more muscles sections of muscles in a cross-section of a subject (e.g., the subject 104 of FIG. 1, the subject 204 of FIG. 2, e.g., the subject 302 of FIG. 3).

At block 1104, the method 1100 includes determining initial MTR_{asym} data (e.g., the initial MTR_{asym} data 606-610 of FIG. 6) based on a first main magnetic field inhomogeneity map (e.g., 906 of FIG. 9) in the ROIs (e.g., 304, 306, 308 of FIG. 3) acquired at time instance (e.g., the first time 902 of FIG. 9). The initial MTR_{asym} data is acquired based on the frequency offset pair during a predetermined acquisition time. For example, the predetermined acquisition time per frequency offset is five seconds, such that the temporal resolution for the frequency offset pair is ten seconds. Because a single frequency offset pair is acquired, the temporal resolution is defined by the frequency offset pair. Conventional methods rely on at least three frequency offset pairs to account for inhomogeneity which increases the acquisition time three-fold. Continuing the example from above with a five second predetermined acquisition time per frequency offset, the temporal resolution for a conventional method would be thirty seconds. The systems and methods described herein thus increase the temporal resolution three-fold such that more data can be acquired in a shorter period of time. This makes it possible to track rapid changes in concentrations of the target molecule.

At block 1106, the method 1100 includes identifying a correction function (e.g., the correction function 612-616 of FIG. 6A-7C) based on the initial MTR_{asym} data at the first time and the pre-event main magnetic field B₀ inhomogeneity. For each pixel, i, in each ROI, the initial MTR_{asym} data is plotted against the corresponding pre-event B₀ inhomogeneity values at the corresponding pixel. The initial MTR_{asym} data is fitted to determine the correction function. As one example, the correction function is a 4th-order polynomial function f.

At block 1108, the method 1100 includes applying the saturation pulse (e.g., second saturation pulse 914 of FIG. 9) for the positive frequency offset and the negative frequency offset to the ROI at a second time after the first time. The first time and the second time are separated by an event (e.g., the event 502 of FIG. 5, the event 912 of FIG. 9), such as an exercise of one or more muscles of the ROI.

At block 1110, the method 1100 includes determining subsequent MTR_{asym} data (e.g., the subsequent MTR_{asym} data 702-706 of FIG. 7) based on a second main magnetic field inhomogeneity map (e.g., the second main magnetic field inhomogeneity 920 of FIG. 9) for the second time. The correction can also involve second applied magnetic field inhomogeneity map (e.g., the second applied magnetic field inhomogeneity 922 of FIG. 9). Due to the event, the subsequent MTR_{asym} data varies from the initial MTR_{asym} data, based on the changes in the concentration of the target molecule, ΔCEST, and changes in the B₀ inhomogeneity at the second time caused by the event, for example, exercise.

At block 1112, the method 1100 includes applying the correction function to the subsequent MTR_{asym} data. The correction function is used to model the B₀ inhomogeneity at the second time.

At block 1114, the method 1100 includes calculating a change in concentration (e.g., ΔCEST 806-810 of FIG. 8) of the target molecule between the first time and the second time based on the subsequent MTR_{asym} data. By the subtracting the B₀ inhomogeneity at the second time as fit by the correction function from the subsequent MTR_{asym} data acquired after the event, the change in the concentration of the target molecule is calculated as highly temporally resolved CEST values at every point in the ROI.

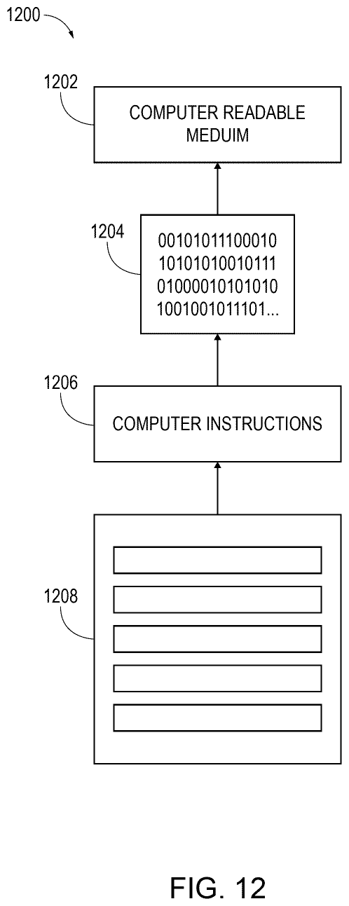

Still another embodiment involves a computer-readable medium including processor-executable instructions configured to implement one or more embodiments of the techniques presented herein. An embodiment of a computer-readable medium or a computer-readable device devised in these ways is illustrated in FIG. 12, wherein an implementation 1200 includes a non-transitory computer-readable medium 1202, such as a flash drive, a platter of a hard disk drive, etc., on which is encoded computer-readable data 1204. This encoded computer-readable data 1204 such as binary data including a plurality of zero's and one's as shown in encoded computer-readable data 1204, in turn includes a set of processor-executable computer instructions 1206 configured to operate according to one or more of the principles set forth herein. In one such embodiment, the implementation 1200, the processor-executable computer instructions 1206 may be configured to perform a method 1208, such as the method 1100 of FIG. 11. In another embodiment, the processor-executable computer instructions 1206 may be configured to implement a system, such as the magnetic resonance application 100 of FIG. 1. Many such computer-readable media may be devised by those of ordinary skill in the art that are configured to operate in accordance with the techniques presented herein.

As used in this application, the terms “component”, “module,” “system”, “interface”, and the like are generally intended to refer to a computer-related entity, either hardware, a combination of hardware and software, software, or software in execution. For example, a component may be, but is not limited to being, a process running on a processor, a processor, an object, an executable, a thread of execution, a program, or a computer. By way of illustration, both an application running on a controller and the controller may be a component. One or more components residing within a process or thread of execution and a component may be localized on one computer or distributed between two or more computers.

Further, the claimed subject matter is implemented as a method, apparatus, or article of manufacture using standard programming or engineering techniques to produce software, firmware, hardware, or any combination thereof to control a computer to implement the disclosed subject matter. Of course, many modifications may be made to this configuration without departing from the scope or spirit of the claimed subject matter.

Generally, embodiments are described in the general context of “computer readable instructions” being executed by one or more computing devices. Computer readable instructions may be distributed via computer readable media as will be discussed below. Computer readable instructions may be implemented as program modules, such as functions, objects, Application Programming Interfaces (APIs), data structures, and the like, that perform one or more tasks or implement one or more abstract data types. Typically, the functionality of the computer readable instructions are combined or distributed as desired in various environments.

What have been described above are examples. It is, of course, not possible to describe every conceivable combination of components or methodologies, but one of ordinary skill in the art will recognize that many further combinations and permutations are possible. Accordingly, the disclosure is intended to embrace all such alterations, modifications, and variations that fall within the scope of this application, including the appended claims. As used herein, the term “includes” means includes but not limited to, the term “including” means including but not limited to. The term “based on” means based at least in part on. Additionally, where the disclosure or claims recite “a,” “an,” “a first,” or “another” element, or the equivalent thereof, it should be interpreted to include one or more than one such element, neither requiring nor excluding two or more of such elements.

A “value” as used herein may include, but is not limited to, a numerical or other kind of value or level such as a percentage, a non-numerical value, a discrete state, a discrete value, a continuous value, among others. The term “value of X” or “level of X” as used throughout this detailed description and in the claims refers to any numerical or other kind of value for distinguishing between two or more states of X. For example, in some cases, the value of X may be given as a percentage between 0% and 100%. In other cases, the value of X could be a value in the range between 1 and 10. In still other cases, the value of X may not be a numerical value, but could be associated with a given discrete state, such as “not X”, “slightly x”, “x”, “very x” and “extremely x”.

In this description, unless otherwise stated, “about,” “approximately” or “substantially” preceding a parameter means being within +/−10 percent of that parameter. Modifications are possible in the described embodiments, and other embodiments are possible, within the scope of the claims.

Further, unless specified otherwise, “first”, “second”, or the like are not intended to imply a temporal aspect, a spatial aspect, an ordering, etc. Rather, such terms are merely used as identifiers, names, etc. for features, elements, items, etc. For example, a first channel and a second channel generally correspond to channel A and channel B or two different or two identical channels or the same channel. Additionally, “comprising”, “comprises”, “including”, “includes”, or the like generally means comprising or including, but not limited to.

It will be appreciated that several of the above-disclosed and other features and functions, or alternatives or varieties thereof, may be desirably combined into many other different systems or applications. Also, that various presently unforeseen or unanticipated alternatives, modifications, variations or improvements therein may be subsequently made by those skilled in the art which are also intended to be encompassed by the following claims.

What is claimed is:

1. A method for determining a concentration of a target molecule in a region of interest (ROI) in a subject comprising:
applying a saturation pulse for a positive frequency offset and a negative frequency offset corresponding to the positive frequency offset based on the target molecule to the ROI at a first time;
determining initial magnetic transfer ratio asymmetry (MTR_{asym}) data based on a first main magnetic field for the first time;
identifying a correction function based on the initial MTR_{asym} data at the first time;
applying the saturation pulse for the positive frequency offset and the negative frequency offset to the ROI at a second time after the first time;
determining subsequent MTR_{asym} data based on a second main magnetic field for the second time;
applying the correction function to the second main magnetic field inhomogeneity; and
calculating a change in concentration of the target molecule between the first time and the second time based on the subsequent MTR_{asym} data.

2. The method of claim 1, wherein the first time and the second time are separated by an event that physically affects the ROI.

3. The method of claim 2, wherein the event is an exercise comprising a movement of at least one muscle present in the ROI.

4. The method of claim 2, wherein the event is a metabolic chemical reaction that effects an anatomy of the subject in the ROI.

5. The method of claim 1, wherein identifying the correction function includes regression analysis.

6. The method of claim 1, wherein the correction function is a fourth order polynomial.

7. The method of claim 1, wherein the target molecule is creatine and the positive frequency offset is +1.8 parts per million (ppm) and the negative frequency offset is −1.8 ppm.

8. The method of claim 1, wherein the target molecule is gamma-aminobutyric acid, glutamate, myo-inositol, adenosine triphosphate (ATP), phospho-creatine, creatine, glycine, proline, albumin, alanine, or aspartate.

9. A system for determining a concentration of a target molecule in a region of interest (ROI) of a subject:
a memory for storing machine-readable instructions; and
a processor core for accessing the machine-readable instructions and executing the machine-readable instructions as operations, the operations comprising:
applying a saturation pulse for a frequency offset pair based on the target molecule to the ROI at a first time;
determining initial magnetic transfer ratio asymmetry (MTR_{asym}) data based on a first main magnetic field for the first time;
identifying a correction function based on the initial MTR_{asym} data at the first time;
applying the saturation pulse for the frequency offset pair to the ROI at a second time after the first time;
determining subsequent MTR_{asym} data based on a second main magnetic field inhomogeneity for the second time;
applying the correction function to the second main magnetic field inhomogeneity; and
calculating a change in concentration of the target molecule between the first time and the second time based on the subsequent MTR_{asym} data.

10. The system of claim 9, wherein the first time and the second time are separated by an event that physically affects the ROI.

11. The system of claim 9, wherein the target molecule is creatine and the frequency offset pair includes a positive frequency offset is +1.8 parts per million (ppm) and a negative frequency offset is −1.8 ppm.

12. The system of claim 9, wherein the frequency offset pair includes a single positive frequency offset and a single negative frequency offset.

13. The system of claim 9, wherein the ROI includes a first muscle and a second muscle and the correction function includes a first correction function corresponding to the first muscle and a second correction function corresponding to the second muscle.

14. The system of claim 13, wherein the first correction function and the second correction function are fourth order polynomials, and the change in the concentration of the target molecule is calculated for the first muscle and the second muscle.

15. A non-transitory machine-readable medium having machine-readable instructions for an MR system causing a processor to execute operations, the operations comprising:
applying a saturation pulse for a positive frequency offset and a negative frequency offset corresponding to the positive frequency offset based on a target molecule to a region of interest (ROI) of a subject at a first time;
determining initial magnetic transfer ratio asymmetry (MTR_{asym}) data based on a first main magnetic field inhomogeneity for the first time;
identifying a correction function based on the initial MTR_{asym} data at the first time;
applying the saturation pulse for the positive frequency offset and the negative frequency offset to the ROI at a second time after the first time;
determining subsequent MTR_{asym} data based on a second main magnetic field inhomogeneity for the second time;
applying the correction function to the second main magnetic field inhomogeneity; and
calculating a change in concentration of the target molecule between the first time and the second time based on the subsequent MTR_{asym} data.

16. The medium of claim 15, wherein the ROI includes a plurality of muscles of the subject and the first time and the second time are separated by an exercise of the plurality of muscles.

17. The medium of claim 16, wherein the plurality of muscles includes a first muscle and a second muscle and the correction function includes a first correction function corresponding to the first muscle and a second correction function corresponding to the second muscle.

18. The medium of claim 15, wherein the target molecule is creatine, the positive frequency offset is +1.8 parts per million (ppm) and the negative frequency offset is −1.8 ppm.

19. The medium of claim 15, wherein identifying the correction function includes quartic regression.

20. The medium of claim 15, wherein the correction function is a fourth order polynomial.
